(19) United States
(12) Patent Application Publication
(10) Pub. No.: US 2024/0419156 A1
(43) Pub. Date: Dec. 19, 2024

(54) SEMICONDUCTOR FABRICATION CONTROL SYSTEM

(71) Applicant: Analog Devices International Unlimited Company, Limerick (IE)

(72) Inventors: Julius Seville Mallari, Cavite (PH); John Stephen Nichols, Muntinlupa City (PH); David Eguia, Taguig City (PH); Mariano Jr. Masagca Solero, Muntinlupa City (PH); Vermont P. Sanchez, Cavite (PH); Haydie L. Rodriguez, Dasmarinas City (PH)

(73) Assignee: Analog Devices International Unlimited Company, Limerick (IE)

(21) Appl. No.: 18/732,474

(22) Filed: Jun. 3, 2024

Related U.S. Application Data
(60) Provisional application No. 63/521,025, filed on Jun. 14, 2023.

(51) Int. Cl. G05B 19/418; H01L 21/66; H01L 21/67

(52) U.S. Cl. CPC G05B 19/4189; H01L 21/67276; H01L 22/20; G05B 2219/45031

(57) ABSTRACT

A semiconductor fabrication control system and method of operation can include: detecting a status with a control board communicatively coupled to a semiconductor fabrication tool; collecting process information from the semiconductor fabrication tool with the control board based on the status changing or a predetermined time elapsing; storing the process information to a server with the control board communicatively coupled to the server by a network connection; and engaging an auto-stop mechanism of the semiconductor fabrication tool to prevent the semiconductor fabrication tool from running based on the process information being wrong.

### TECHNICAL FIELD

This disclosure relates to semiconductor manufacturing, more particularly to control systems for manufacturing equipment.

### BACKGROUND

Semiconductors have rapidly become an integral part of modern life across the globe; finding application in manufacturing, public infrastructure, and consumer devices. Illustratively, semiconductors can be found in cellphones and computers but are also found in things as diverse as coffee makers, lights, high-speed rail, and aircraft.

Semiconductors are produced in advanced manufacturing facilities with strict process and quality controls. These manufacturing facilities are large, complex, and rely on many various fabrication tools.

Testing machines and handling machines are two types of fabrication tool and are used herein as non-limiting descriptive examples. Fabrication tools can also include various machines performing many different processes required to produce semiconductors.

As semiconductor factories age, new fabrication tools are often brought in while older fabrication tools, in daily use for decades, continue to be used. Many problems unique to the semiconductor fabrication industry arise when both new tools and old tools are required to meet the ever-increasing process and quality standards needed to manufacture state of the art semiconductors.

Next generation semiconductors will require even greater control of the manufacturing process than is currently available. Competitive next generation fabrication systems should provide solutions to meet these future requirements.

Solutions should include monitoring and a real-time control over the process to prevent defects and jams. These next generation fabrication systems should also provide real time monitoring, reduced maintenance requirements, and remote production stop functions (e.g., an auto-stop function).

Importantly, the ability to control the fabrication tools in a closed-loop and collect fabrication tool data remains a critical need for competitive next generation fabrication systems. For example, semiconductors moving through fabrication tools are extremely small and sensitive to defects from electrostatic discharge (ESD), physical contamination, and mechanical forces.

During the handling process, it is important to ensure that all parts of the handling machine, where the semiconductor product passes through, are properly grounded to prevent damage due to ESD. Collecting fabrication tool data to ensure proper grounding of the fabrication tool can increase defect prevention from ESD.

Prior developments required the handling machines to be manually tested at multiple ground points during setup procedures. These setup procedures are conducted each time the handling machine is set up or maintenance is performed.

This form of manual testing can take between ten and fifteen minutes, which in a factory setting, must be multiplied by the number of handling machine in use and by each maintenance or setup procedure conducted. Furthermore, the current manual testing procedures require the handling machine to be taken off-line and out of the production line, which can negatively impact factory throughput, cycle times, tool availability, tool down time, maintenance tasks, maintenance training, and other production metrics.

Closed-loop control should allow the fabrication tool to be turned off with a mechanism, such as an auto-stop mechanism which may include circuitry to implement the auto-stop, for example, and which is important when the fabrication tool is in an out of control situation that can arise in different manufacturing critical processes. Data collection from the fabrication tools can be done manually but this manual data collection requires a manual connection via a serial cable.

Data is therefore usually collected only during maintenance actions increasing down time, maintenance hours, and maintenance tasks. There have been many attempts to design fabrication tools that ensure proper grounding to prevent ESD damage and save time, proactively address issues related to yield, jams, and temperature.

Many industry road maps have identified significant gaps between the large demand of next generation semiconductor products and the ability of currently available semiconductor fabrication tools to provide closed-loop control based on fabrication data collection. Furthermore, the ever-increasing competitive pressures require fabrication solutions to enable high factory throughput, low cycle times, increased tool availability, decreased tool down time, decreased maintenance tasks, decreased maintenance training, and importantly decreased costs.

Current technologies are not capable of providing closed-loop control based on fabrication data collection. One prior development included the use of off the shelf cell controller products. These prior developments could either be installed in a handling machine, a testing machine, or in between the two.

These off the shelf cell controllers do not provide fabrication data collection like continuous ground monitoring or real time yield monitoring. Neither do these off the shelf cell controllers have the capability of full closed loop integration between handler and tester with auto-stop when a trigger is reached.

These off the shelf cell controllers also come at a very high cost ranging from several thousand to tens of thousands of dollars per setup. These costs exclude annual subscription fees and, if used in a factory setting, should be multiplied by each handler machine that the off the shelf cell controller is used on.

In view of the ever-increasing market pressures for sophisticated semiconductors and their accompanying manufacturing requirements, it is critical that solutions be found to provide closed-loop control based on fabrication data collection.

Thus, a need remains for manufacturing control systems providing closed-loop control based on fabrication data collection. Solutions to these problems have been long sought but prior developments have not taught or suggested any solutions and, thus, solutions to these problems have long eluded those skilled in the art.

### BRIEF DESCRIPTION OF THE DRAWINGS

The control system is illustrated in the figures of the accompanying drawings which are meant to be exemplary and not limiting, in which like reference numerals are intended to refer to like components, and in which:

FIG. 1 is a graphical view of the control system.

FIG. 2 is a top view of the control board and connections of FIG. 1 in a first embodiment.

FIG. 3 is a top view of the control board of FIG. 1 in a second embodiment.

FIG. 4 is a method of operating the control system.

### DETAILED DESCRIPTION

In the following description, reference is made to the accompanying drawings that form a part hereof, and in which are shown by way of illustration, embodiments in which the control system may be practiced. It is to be understood that other embodiments may be utilized and structural changes may be made without departing from the scope of the control system.

When features, aspects, or embodiments of the control system are described in terms of steps of a process, an operation, a control flow, or a flow chart, it is to be understood that the steps can be combined, performed in a different order, deleted, or include additional steps without departing from the control system as described herein.

The control system is described in sufficient detail to enable those skilled in the art to make and use the control system and provide numerous specific details to give a thorough understanding of the control system; however, it will be apparent that the control system may be practiced without these specific details.

In order to avoid obscuring the control system, some well-known system configurations and descriptions are not disclosed in detail. Likewise, the drawings showing embodiments of the system are semi-diagrammatic and not to scale and, particularly, some of the dimensions are for the clarity of presentation and are shown greatly exaggerated in the drawing FIGS. As used herein, the term “communicatively coupled” means a connection between elements by which communications can be sent or received such as through a wired electrical connection, an optical cable connection, or a wireless connection.

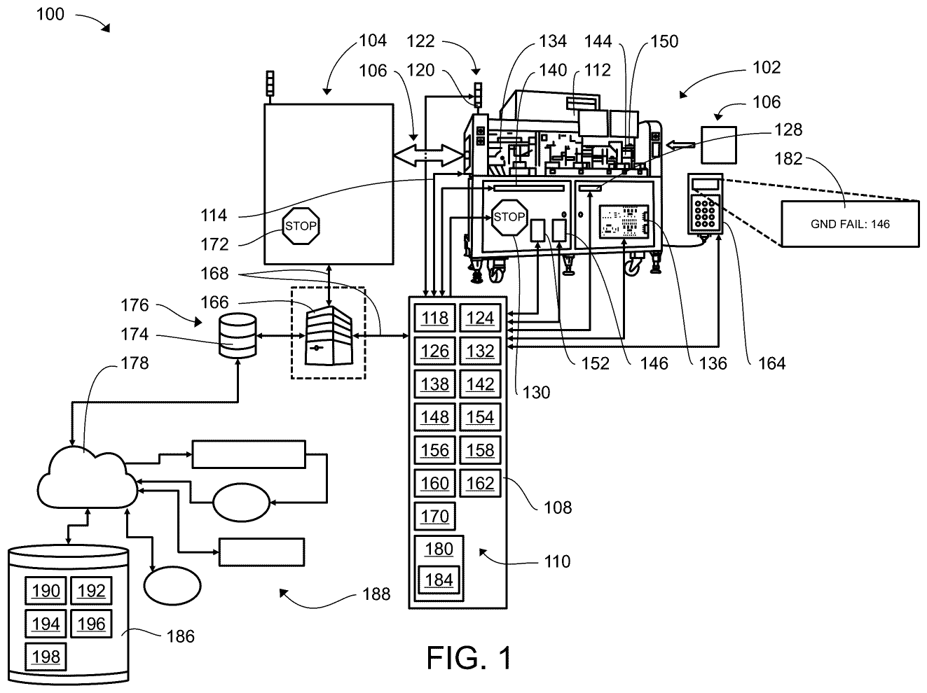

Referring now to FIG. 1, therein is shown a graphical view of the control system 100. One step in the semiconductor manufacturing process requires that the semiconductors be tested to ensure quality and functionality before reaching customers. Such testing involves the use of testing machines and handling machines.

Semiconductor fabrication tools can include testing machines and handling machines but can also include other tools used to fabricate semiconductors including deposition machines, lithography machines, etching machines, implant machines, and packaging machines. The control system 100 is described herein with regard to a handling machine 102 and a testing machine 104 for descriptive convenience and is not intended to limit the scope of the invention unless recited in the claims.

The handling machine 102 can be loaded with semiconductor products 106, which are individually transported by the handling machine 102 to the testing machine 104 where the semiconductor products 106 are tested for quality and functionality.

The handling machine 102 can either be a gravity fed type of handler or a pick and place type of handler. The handling machine 102 and testing machine 104, as depicted, can handle and test packaged semiconductor chips. Typically, a pair comprising one of the handling machines 102 and one of the testing machines 104 can test around one thousand to three thousand units per hour.

Other implementations are contemplated that can handle, test, and process wafers as well as packaged semiconductor chips. The handling machines 102 and the testing machines 104 will be physically different when processing wafers or chips, but the control system 100 can provide process control for each kind of fabrication tool. Wafer fabrication tools are merely found in an earlier phase of fabrication.

The handling machine 102 and the testing machine 104 can be communicatively coupled to a control board 108, which will collect process information 110. The process information 110 is contemplated to include information collected from the fabrication tools whether running, stopped, or idle. That is, the process information 110 can be information about the handling machine 102, the testing machine 104, or even the semiconductor products 106 themselves.

The control board 108 can be communicatively coupled to the handling machine 102 in many ways; however, when the handling machine 102 is a newer type of handling machine 102 with a CPU 112 controlling the handling machine 102, the control board 108 can be communicatively coupled to the handling machine 102 with a serial connection 114, through which, the process information 110 transfers sequentially or serially between the control board 108 and the CPU 112.

The serial connection can be any type of serial connection, however because even new fabrication tools share backwards compatibility with older tools, the serial connection can be a recommended standard 232 (RS232) connection 114, for example. Hardware that is compliant with a similar standard such as RS422 and RS485 are also contemplated as are other serial connections including Ethernet and USB.

The control board 108 can collect the process information 110 by sending a query to the handling machine 102 using the handling machine's communication protocol. When the handling machine 102 is a newer type with a controlling CPU 112, the control board 108 can collect each type of the process information 110 through the serial connection 114.

However, when the handling machine 102 is an older machine that does not rely on the CPU 112 for control and management, other connections can be used by the control board 108 to collect the process information 110 from the handling machine 102.

Illustratively, for example, the control board 108 can collect a handler status 118 of the handling machine 102 as one piece of the process information 110. The handler status 118 can be collected with a light pole sensor 120 connected to a light pole 122 of the handling machine 102.

The light pole 122 can be a tower-light status indicator for operating the handling machine 102. The light pole sensor 120 can monitor the handler status 118 displayed with the light pole 122, including ON, OFF, or BLINKING.

The handler status 118 is used to determine the handling machine's 102 activities. A green light ON means the handling machine 102 is Up and running in production, while a red light ON means the handling machine 102 is Down and production has stopped, a BLINKING red could mean that the handling machine 102 has jam or similar production halting condition.

The control board 108 can collect the process information 110 either synchronously or asynchronously. Asynchronous data collection can happen when the control board 108 detects a change in the handler status 118 of the handling machine 102 based on a change in the state of the lights within the light pole 122.

The control board 108 can monitor the state of the light pole 122 for any changes, and once a change is detected, the control board 108 can query and collect the process information 110 from the handling machine 102. For example, asynchronous data collection can happen when the control board 108 gets the process information 110 from the handling machine 102 whenever the light pole 122 state changes from Down to Up or Up to Down.

Synchronous data collection happens when the control board 108 gets the process information 110 from the handling machine 102 at predetermined times such as every hour. One example of the process information 110 collected synchronously is product count 124, or number of parts processed through the handling machine 102. One reason for this is because when the handling machine 102 runs for hours without any downtime, it will take a while before the control board 108 can collect the product count 124.

Continuing with the above example, the control board 108 can collect handler temperature readings 126 as one piece of the process information 110. The handler temperature readings 126 can be taken from multiple temperature sensors 128 positioned on the handling machine 102, however particular attention of temperature can be along the path of the semiconductor product 106 through the handling machine 102.

The handler temperature readings 126 can be compared with a set up temperature and track any temperature shifts for quality control, tool health, and maintenance purposes. It is contemplated that the handler temperature readings 126 can be recorded and compared to a temperature threshold above and below a set-up temperature or a process control required temperature.

The handler temperature readings 126 at multiple points can be compared to a site-to-site temperature variance threshold for determining an acceptable temperature variance from site-to-site across the temperature sensors 128. If the handler temperature readings 126 exceed the temperature threshold or the site-to-site temperature variance threshold, the control board 108 can stop the handling machine 102 by triggering a handler auto-stop 130 with a serial communication.

As used herein, a threshold can be exceeded based on information or data moving from one side of the threshold to the other either in a positive or negative direction. Exceeding a threshold can also mean data being either above an upper threshold or below a lower threshold.

The handler auto-stop 130 is an auto-stop mechanism which may include circuitry and software, in any combination, to prevent the handling machine 102 from running based on the process information 110 being wrong, which means a process control is breached, a threshold related to the process information 110 is exceeded, or an unexpected value is detected. The handler auto-stop 130 can for example be a part of an emergency off system, a door interlock system, or other interlock system of the handling machine 102.

Illustratively, the handler auto-stop 130 can be engaged based on the detection of an out of control state by the control board 108. The control board 108 can engage the handler auto-stop 130 by disrupting the interlock system or emergency system of the handling machine 102. The handler auto-stop 130 thereby provides closed-loop control of the handling machine 102, which is important when the fabrication tool is in an out of control state, which can arise in different manufacturing critical processes.

The handler auto-stop 130 can therefore prevent possible production defects from proliferating due to the out of control state and provide an opportunity for corrective action to be taken prior to impacting subsequent semiconductor product 106 handled by the handling machine 102. The handler temperature readings 126 can be one trigger used to auto-stop the handling machine 102 or the handling machine 102 and testing machine 104 together.

The handler temperature readings 126 can be collected either asynchronously based on a change in the handler status 118 of the light pole 122 or synchronously based on a predetermined time internal. When the handling machine 102 is a newer type with a controlling CPU 112, the control board 108 can collect the handler temperature readings 126 as one type of the process information 110 through the serial connection 114.

The control board 108 can further collect handler ground readings 132 as one piece of the process information 110. The handler ground readings 132 can be continuously monitored from multiple ground sensors 134 positioned on the handling machine 102, however particular attention to handler ground readings 132 along the path of the semiconductor product 106 through the handling machine 102 is of greater importance. The handler ground readings 132 can be collected, processed, stored, and transmitted by the continuous ground monitoring board 136 to the control board 108.

The handler ground readings 132 can be compared with a process control ground requirement and track any grounding shifts for quality control, tool health, and maintenance purposes. It is contemplated that the handler ground readings 132 can be recorded and compared to a ground threshold above and below a set-up or process control required ground level.

It has been discovered that recording the handler ground readings 132 automatically, even when the handler is running, can save 27.25 handler hours per week. Thus, overall equipment efficiency is improved which is an important metric in cost constrained semiconductor fabrication industries.

The handler ground readings 132 at multiple points can be compared to a site-to-site ground variance threshold for determining an acceptable ground variance from site-to-site across the ground sensors 134. If the handler ground readings 132 exceed the ground threshold or the site-to-site ground variance threshold, the control board 108 can stop the handling machine 102 by triggering the handler auto-stop 130 or auto-stop circuitry within the handling machine 102.

The handler auto-stop 130 can therefore prevent possible production defects from proliferating due to the out of control state and provide an opportunity for corrective action to be taken prior to impacting subsequent semiconductor product 106 handled by the handling machine 102. The handler ground readings 132 can be one trigger used to auto-stop the handling machine 102 or the handling machine 102 and testing machine 104 together.

The handler ground readings 132 can be collected either asynchronously based on a change in the handler status 118 of the light pole 122 or synchronously based on a predetermined time internal. When the handling machine 102 is a newer type with a controlling CPU 112, the control board 108 can collect the handler ground readings 132 as one type of the process information 110 through the serial connection 114.

The control board 108 can yet further collect handler vibration readings 138 as one piece of the process information 110. The handler vibration readings 138 can be taken from multiple vibration sensors 140 positioned on the handling machine 102, however particular attention to handler vibration readings 138 along the path of the semiconductor product 106 through the handling machine 102 is of greater importance.

The handler vibration readings 138 can be directly sent to the control board 108 from the vibration sensors 140 with a serial connection. The serial connection can be any suitable serial connection such as I2C, for example.

The handler vibration readings 138 can be compared with a process control vibration requirement and track any vibration shifts for quality control, tool health, and maintenance purposes. It is contemplated that the handler vibration readings 138 can be recorded and compared to a vibration threshold above and below a set-up or process control required vibration level.

The handler vibration readings 138 at multiple points can be compared to a site-to-site vibration variance threshold for determining an acceptable vibration variance from site-to-site across the vibration sensors 140. If the handler vibration readings 138 exceed the vibration threshold or the site-to-site vibration variance threshold, the control board 108 can stop the handling machine 102 by triggering the handler auto-stop 130 or auto-stop circuitry within the handling machine 102.

The handler auto-stop 130 can therefore prevent possible production defects from proliferating due to the out of control state and provide an opportunity for corrective action to be taken prior to impacting subsequent semiconductor product 106 handled by the handling machine 102. The handler vibration readings 138 can be one trigger used to auto-stop the handling machine 102 or the handling machine 102 and testing machine 104 together.

The handler vibration readings 138 can be collected either asynchronously based on a change in the handler status 118 of the light pole 122 or synchronously based on a predetermined time internal. When the handling machine 102 is a newer type with a controlling CPU 112, the control board 108 can collect the handler vibration readings 138 as one type of the process information 110 through the serial connection 114 and would not utilize the continuous ground monitoring board 136 to collect the handler vibration readings 138.

The control board 108 can yet further collect handler jam readings 142 as one piece of the process information 110. The handler jam readings 142 can be taken from multiple jam sensors 144 positioned on the handling machine 102 in contact with elements of the handling machine 102 that contact the semiconductor product 106. The handler jam readings 142 can be collected, processed, stored, and transmitted by the sensor interface board 146 to the control board 108.

The handler jam readings 142 are tracked for quality control, tool health, and maintenance purposes. The handler jam readings 142 can be compared to a process control threshold limiting the number of jams detected during a specified amount of time or during a specified amount of product run through the handling machine 102.

If the handler jam readings 142 exceed the jam threshold, the control board 108 can stop the handling machine 102 by triggering the handler auto-stop 130 or auto-stop circuitry within the handling machine 102.

The handler auto-stop 130 can therefore prevent possible production defects from proliferating due to the out of control state and provide an opportunity for corrective action to be taken prior to impacting subsequent semiconductor product 106 handled by the handling machine 102. The handler jam readings 142 can be one trigger used to auto-stop the handling machine 102 or the handling machine 102 and testing machine 104 together.

The handler jam readings 142 can be collected either asynchronously based on a change in the handler status 118 of the light pole 122 or synchronously based on a predetermined time internal. When the handling machine 102 is a newer type with a controlling CPU 112, the control board 108 can collect the handler jam readings 142 as one type of the process information 110 through the serial connection 114 and would not utilize the sensor interface board 146.

The control board 108 can yet further collect handler bin readings 148 as one piece of the process information 110. The handler bin readings 148 can be taken from a bin sensor 150 for the semiconductor product 106 after it is run through the testing machine 104 and sent back to the handling machine 102.

After the testing machine 104 has tested the semiconductor product 106 and has assigned a bin based on errors, defects, or performance of the semiconductor product 106, the handling machine 102 can place the semiconductor products 106 into physically separate containers, referred to as “bins”. Many typical testing machines 104 will bin the semiconductor product 106 based on a pass/fail response from the semiconductor product 106 during testing. The handler bin readings 148 can be collected, processed, stored, and transmitted by the tester interface board 152 to the control board 108.

The handler bin readings 148 are tracked for quality control, tool health, and maintenance purposes. The handler bin readings 148 can be further processed to determine other forms of the process information 110 including soak time data 154, which can be a measure of the time the semiconductor product 106 spent in process within the fabrication tools including the handling machine 102 and the testing machine 104.

The handling machine 102 can further track sitemap data 156. The sitemap data 156 is captured from the handling machine 102 using a separate command specifically for capturing the sitemap data 156.

The sitemap data 156 is the handling position of the semiconductor product 106 as it moves through the handling machine 102. For example, a quad site handler and sitemap could be 1,2,3,4 or 4,3,2,1 or 1,2,4,3. The sitemap data 156 can depend on the setting required by the test program and the tools used to process the testing.

The handler bin readings 148 can be collected either asynchronously based on a change in the handler status 118 of the light pole 122 or synchronously based on a predetermined time internal. When the handling machine 102 is a newer type with a controlling CPU 112, the control board 108 can collect the handler bin readings 148, the soak time data 154, and the sitemap data 156 as types of the process information 110 through the serial connection 114, and would not utilize the tester interface board 152.

If the handler bin readings 148 show a wrong bin, the soak time data 154 exceeds a threshold, or the sitemap data 156 is wrong, the control board 108 can stop the handling machine 102 by triggering the handler auto-stop 130 or auto-stop circuitry within the handling machine 102.

The control board 108 can further collect debagging data 158, fault data 160, and process control data 162. The debagging data 158, the fault data 160, and the process control data 162 can be collected from a keypad 164.

The debagging data 158 can be controls and time stamps from a debagging process step required to load the handling machine 102. The fault data 160 can be any faults generated by the handling machine 102, along with their timestamps. The process control data 162 can be a record of any commands input into the handling machine 102 through the keypad 158 and their timestamps.

The debagging data 158, the fault data 160, and the process control data 162 can be collected either asynchronously based on a change in the handler status 118 of the light pole 122 or synchronously based on a predetermined time internal. When the handling machine 102 is a newer type with a controlling CPU 112, the control board 108 can collect the debagging data 158, the fault data 160, and the process control data 162 as types of the process information 110 through the serial connection 114.

It is contemplated that the control board 108 can collect other types of process information 110 based on the needs of the fabrication process and the fabrication tool. It is contemplated that the control board 108 can retrieve the process information 110 including: the handler status 118 from the light pole 122, the handler temperature readings 126 from the temperature sensors 128, the handler ground readings 132 from the ground sensors 134 through the continuous ground monitoring board 136, the handler jam readings 142 from the jam sensors 144 through the sensor interface board 146, the handler bin readings 148 from the bin sensor 150 through the tester interface board 152, the debagging data 158 from the keypad 164, the fault data 160 from the keypad 164, and the process control data 162 from the keypad 164 using a serial connection and using serial communication between the control board 108 and other elements.

The control board 108 can be connected to the testing machine 104 with a server 166 therebetween. The server 166 can be communicatively coupled to the testing machine 104 and to the control board 108 with network connections 168.

It is contemplated that the network connections 168 can be any suitable connection, however because fabrication tools interface with both old and new tools, an RS485 network connection, a TCP/IP network connection, an ethernet connection, or even a wireless connection could be used.

While the network connections 168 are shown and described as communicatively coupling the control board 108 to the server 166, it is contemplated that the network connections 168 could also communicatively couple the control board 108 to an internal internet, for example. The network connections 168 can couple multiple handling machines 102 to the server 166, in some implementations thirty handling machines 102 can be coupled to a single server 166.

The control board 108 can collect the process information 110 from the testing machine 104 through the server 166 and the network connections 168. For example, the control board 108 can retrieve the process information 110 such as tester temperature readings 174.

The tester temperature readings 170 can be compared with a set up temperature and track any temperature shifts for quality control, tool health, and maintenance purposes. It is contemplated that the tester temperature readings 170 can be recorded and compared to a temperature threshold above and below a set-up temperature or a process control window for a required temperature.

The handler temperature readings 126 at multiple points can be compared to a site-to-site temperature variance threshold for determining an acceptable temperature variance from site-to-site across the testing machine 104. If the tester temperature readings 170 exceed the temperature threshold or the site-to-site temperature variance threshold, the control board 108 can stop the handling machine 102 by triggering the handler auto-stop 130 or the testing machine 104 by triggering a tester auto-stop 172 with a serial connection.

The tester auto-stop 172 is an auto-stop mechanism which may include circuitry and software, in any combination, to prevent the testing machine 104 from running based on the process information 110 being wrong, which means a process control is breached, a threshold related to the process information 110 is exceeded, or an unexpected value is detected. The tester auto-stop 172 can for example be a part of an emergency off system, a door interlock system, or other interlock system of the testing machine 104.

Illustratively, the tester auto-stop 172 can be engaged based on the detection of an out of control state by the control board 108. The control board 108 can engage the tester auto-stop 172 by disrupting the interlock system or emergency system of the testing machine 104. The tester auto-stop 172 thereby provides closed-loop control of the testing machine 104, which is important when the fabrication tool is in an out of control state, which can arise in different manufacturing critical processes.

The tester auto-stop 172 can therefore prevent possible production defects from proliferating due to the out of control state and provide an opportunity for corrective action to be taken prior to impacting subsequent semiconductor product 106 handled by the testing machine 104. The handler temperature readings 126 or the tester temperature readings 170 can be some triggers used to auto-stop the handling machine 102 or the handling machine 102 and testing machine 104 together.

The tester temperature readings 170 can also be used for automatic temperature calibration and adjustments on the handling machine 102. The server 166 can retrieve the process information 110 from the control board 108 and can write the process information 110 onto a return table 174 of a front end database 176.

The return table 174 of the front end database 176 can be fetched by a web service 178. The web service 178 continuously reads the return table 174 of the front end database 176 and sends back a response 180 to the control board 108.

The response 180 can be used to determine a communication status of the network connection 168 between the server 166 and the control board 108. The control board 108 can display the communication status “online” on a display 182 of the keypad 164 based on the response 180 being received by the control board 108 from the server 166 within a time window.

The control board 108 can display the communication status “offline” on the display 182 of the keypad 164 based on the response 180 not being received by the control board 108 from the server 166 within a time window.

The response 180 can also include an auto-stop trigger 184. The control board 108 can trigger the handler auto-stop 130, the tester auto-stop 172, or both based on receiving the auto-stop trigger 184 within the response 180. The auto-stop trigger 184 can be generated by the server 166 or the web service 178 based on a comparison between the process information 110 and thresholds or based on an analysis of the process information 110.

For example, if one of the process information 110, such as the handler temperature readings 126, exceeds a threshold; the auto-stop trigger 184 could be included within the response 180 and cause the control board 108 to engage the handler auto-stop 130 and the tester auto-stop 172 forcing a halt to production on the tools. Similarly, if the process information 110 is analyzed and a value is not expected, the auto-stop trigger 184 could be included within the response 180 and cause the control board 108 to engage the handler auto-stop 130 and the tester auto-stop 172 forcing a halt to production on the tools.

The web service 178 can collect the process information 110 through the return table 174 of the front end database 176. The web service 178 can process and analyze the process information 110 to compute the product count through the tool, product count through the tool over time, and product count through the tool per jam. The web service 178 can save the process information 110 together with the product count through the tool, product count through the tool over time, and product count through the tool per jam on a back end database 186.

The server 166 can also retrieve the process information 110 information from the testing machine 104, through the network connections 168 using cron jobs 188 that operate on the web service 178, and can store this process information 110 to the back end database 186. The process information 110 retrieved using the cron jobs 188 can include index time 190, number of products that passed 192, number of products that failed 194, total number of products 196 through the testing machine 104, and lot numbers 198 for the semiconductor products 106 run.

It is contemplated that the process information 110 including the handler bin readings 148, the handler jam readings 142, the handler temperature readings 126, the sitemap data 156, and the soak time data 154 can be analyzed, in the server 166 and with the web service 178 to determine critical jams and compute an efficiency for the handling machine 102, such as number of products run per jam. Critical jams are specific type of jam that cause major problems and require repair before production can begin again.

Critical jams can be detected based on an error code or a combination of the process information 110. It is further contemplated that this process information 110 can be used to alert a support team or maintenance team when the setup yield or efficiency is low.

The process information 110 can further be used to detect incorrect temperature or soak time settings. Other uses of process information 110 include the early detection of issues, data analytics, and even to identify predictive maintenance for the fabrication tool.

The server 166 and web service 178 can further analyze the process information 110 by performing comparisons between part count throughput for both the handling machine 102 and the testing machine 104 to proactively detect mis-binning, which is a major contributor to customer issues.

The control board 108 can therefore be integrated with the server 166 and the web service 178 to save the process information 110 to a database for analysis. The control system 100 is also integrated with the real time jam monitoring, real time yield monitoring, and event driven Out of Control Procedure (OCAP) to detect critical jams and halt the handling machine 102 through the handler auto-stop 130. Event driven OACP is a procedure that is automatically displayed to operators providing instructions to fix the problem.

The web service 178 can also be used to process the process information 110 and detect critical events. Critical events can be events triggering the handler auto-stop 130 to engage and stop the handling machine 102. Alternatively, the web service 178 can process the process information 110 and detect critical events to shut down the testing machine 104 with the tester auto-stop 172.

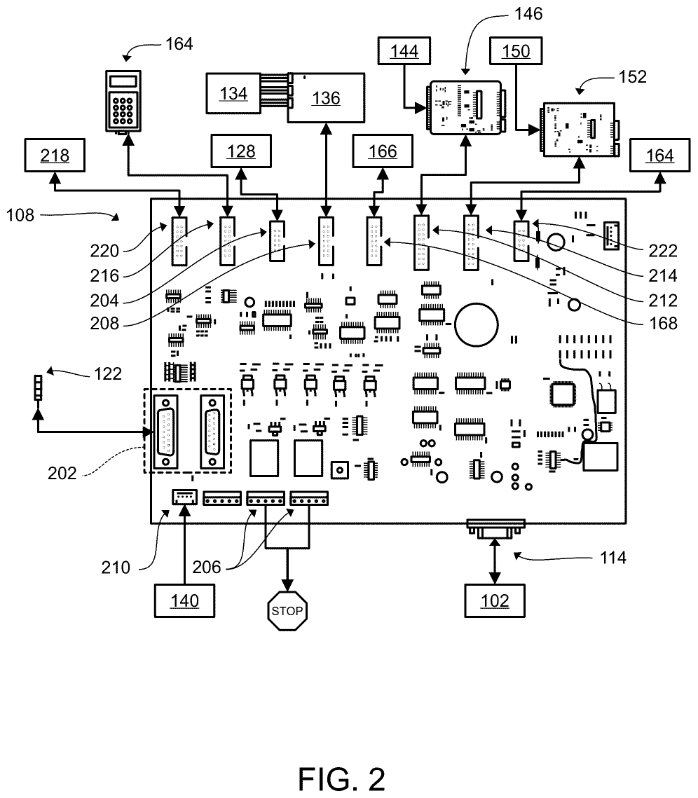

Referring now to FIG. 2, therein is shown a top view of the control board 108 and connections of FIG. 1 in a first embodiment. The control board 108 can be communicatively coupled to the handling machine 102 with the serial connection 114, through which, the process information 110 of FIG. 1 transfers sequentially or serially between the control board 108 and the handling machine 102.

The serial connection can be any type of serial connection, however because even new fabrication tools share backwards compatibility with older tools, the serial connection can be an RS232 connection 114, for example. Hardware that is compliant with a similar standard such as RS422 and RS485 are also contemplated as are other serial connections including Ethernet and USB.

The control board 108 can collect the process information 110 by sending a query to the handling machine 102 using the handling machine's communication protocol. The control board 108 can collect the handler status 118 of FIG. 1 as one piece of the process information 110.

The handler status 118 can be collected by detecting a change of condition at the light pole 122 with a status connection 202. It is contemplated that in one embodiment, the control board 108 could control the status of the light pole 122; while in other embodiments, the control board 108 can merely monitor the status of the light pole 122.

The status connection 202 can be a pair of RS232 connectors communicatively coupled to the light pole 122. The status connection 202 can be a serial connection between the control board 108 and the handling machine 102. It is contemplated that in one embodiment, the control board 108 can control the light pole 122 of the handling machine 102 through the status connection 202.

The control board 108 can also collect the handler temperature readings 126 of FIG. 1 as one piece of the process information 110. The handler temperature readings 126 can be taken from multiple temperature sensors 128 positioned on the handling machine 102 with a temperature monitoring connection 204. The temperature monitoring connection 204 can be a serial ribbon and pin connection between the control board 108 and the handling machine 102.

If the handler temperature readings 126 exceed the temperature threshold or the site-to-site temperature variance threshold, the control board 108 can stop the handling machine 102 by triggering the handler auto-stop 130 with an auto-stop connection 206. The auto-stop connection 206 can be a serial connection with a screw terminal between the control board 108 and the handling machine 102.

The handler auto-stop 130 can be a circuit that stops the handling machine 102 from running when a process control is breached, such as when there is a temperature exceeding a threshold. The handler auto-stop 130 thereby provides closed-loop control of the handling machine 102, which is important when the fabrication tool is in an out of control state that can arise in different manufacturing critical processes.

It is contemplated that the handler auto-stop 130 can be wired into a door interlock of the handling machine 102. When an out of control state is detected by the control board 108, the control board 108 can disrupt the door interlock circuitry of the handling machine 102 to engage the handler auto-stop 130. The handler temperature readings 126 can be one trigger used to auto-stop the handling machine 102 or the handling machine 102 and testing machine 104 of FIG. 1 together.

The handler temperature readings 126 can be collected either asynchronously based on a change in the handler status 118 of the light pole 122 or synchronously based on a predetermined time internal. The control board 108 can further collect the handler ground readings 132 of FIG. 1 as one piece of the process information 110.

The handler ground readings 132 can be continuously monitored from the multiple ground sensors 134 positioned on the handling machine 102. The handler ground readings 132 can be collected, processed, stored, and transmitted by the continuous ground monitoring board 136 to the control board 108 with a ground monitoring connection 208. The ground monitoring connection 208 can be a serial ribbon and pin connection between the control board 108 and the handling machine 102.

If the handler ground readings 132 exceed the ground threshold or the site-to-site ground variance threshold, the control board 108 can stop the handling machine 102 by triggering the handler auto-stop 130 or auto-stop circuitry within the handling machine 102. The handler ground readings 132 can be one trigger used to auto-stop the handling machine 102 or the handling machine 102 and testing machine 104 together. The handler ground readings 132 can be collected either asynchronously based on a change in the handler status 118 of the light pole 122 or synchronously based on a predetermined time internal.

The control board 108 can yet further collect the handler vibration readings 138 of FIG. 1 as one piece of the process information 110. The handler vibration readings 138 can be taken from the vibration sensors 140 positioned on the handling machine 102.

The control board 108 can provide a separate vibration monitoring connection 210. The vibration monitoring connection 210 can provide a connection between the vibration sensors 140 and the control board 108. The vibration monitoring connection 210 can for example be a serial connection such as the I2C connection.

The handler vibration readings 138 can be one trigger used to auto-stop the handling machine 102 or the handling machine 102 and testing machine 104 together. The handler vibration readings 138 can be collected either asynchronously based on a change in the handler status 118 of the light pole 122 or synchronously based on a predetermined time internal.

The control board 108 can yet further collect the handler jam readings 142 of FIG. 1 as one piece of the process information 110. The handler jam readings 142 can be taken from the multiple jam sensors 144 positioned on the handling machine 102 in contact with elements of the handling machine 102 in direct contact with the semiconductor product 106 of FIG. 1.

The handler jam readings 142 can be collected, processed, stored, and transmitted by the sensor interface board 146 to the control board 108 with a sensor interface connection 212. The sensor interface connection 212 can be a serial ribbon and pin connection between the control board 108 and the handling machine 102.

If the handler jam readings 142 exceed the jam threshold, the control board 108 can stop the handling machine 102 by triggering the handler auto-stop 130 or auto-stop circuitry within the handling machine 102. The handler jam readings 142 can be one trigger used to auto-stop the handling machine 102 or the handling machine 102 and testing machine 104 together. The handler jam readings 142 can be collected either asynchronously based on a change in the handler status 118 of the light pole 122 or synchronously based on a predetermined time internal.

The control board 108 can yet further collect the handler bin readings 148 of FIG. 1 as one piece of the process information 110. The handler bin readings 148 can be taken from the bin sensor 150 can collect bin data for the semiconductor product 106 as it is run through the handling machine 102.

The handler bin readings 148 can be collected, processed, stored, and transmitted by the tester interface board 152 to the control board 108 with a tester interface connection 214. The tester interface connection 214 can be a serial ribbon and pin connection between the control board 108 and the handling machine 102.

The handler bin readings 148 can be collected either asynchronously based on a change in the handler status 118 of the light pole 122 or synchronously based on a predetermined time internal. If the handler bin readings 148 are wrong, the control board 108 can stop the handling machine 102 by triggering the handler auto-stop 130 or auto-stop circuitry within the handling machine 102.

The control board 108 can further collect the debagging data 158, the fault data 160, and the process control data 162, all of FIG. 1. The debagging data 158, the fault data 160, and the process control data 162 can be collected from the keypad 164 communicatively coupled to the control board 108 with a keypad connection 216. The keypad connection 216 can be a serial ribbon and pin connection between the control board 108 and the handling machine 102.

The debagging data 158, the fault data 160, and the process control data 162 can be collected cither asynchronously based on a change in the handler status 118 of the light pole 122 or synchronously based on a predetermined time internal.

The control board 108 can be connected to the testing machine 104 with the server 166, therebetween. The server 166 can be communicatively coupled to the testing machine 104 and to the control board 108 with the network connections 168.

The network connections 168 are depicted as a serial ribbon and pin connection between the control board 108 and the server 166. It is contemplated that the network connections 168 can be any suitable connection, however because fabrication tools interface with both old and new tools, an RS485 network connection, a TCP/IP network connection, or an ethernet connection could be used.

While the network connections 168 are shown and described as communicatively coupling the control board 108 to the server 166, it is contemplated that the network connections 168 could also communicatively couple the control board 108 to an internal internet, for example. The network connections 168 can couple multiple handling machines 102 to the server 166, in some implementations thirty handling machines 102 can be coupled to a single server 166.

The control board 108 can be communicatively coupled to sort shuttle sensors 218 for collecting information about a shuttle within the handling machine 102 such as whether the shuttle is empty or full, and whether the shuttle needs operator assistance. The sort shuttle sensors 218 can be communicatively coupled to the control board 108 with a sort shuttle connection 220.

The sort shuttle connection 220 can be a serial ribbon and pin connection between the control board 108 and the handling machine 102. The sorting information can be collected either asynchronously based on a change in the handler status 118 of the light pole 122 or synchronously based on a predetermined time internal.

The control board 108 can further reserve a run-stop connection 222, which provides an additional connection between the keypad 164 and the control board 108. The run-stop connection 222 can be a serial ribbon and pin connection between the control board 108 and the handling machine 102.

The temperature monitoring connection 204, ground monitoring connection 208, sensor interface connection 212, tester interface connection 214, keypad connection 216, sort shuttle connection 220, run-stop connection 222, and the network connections 168 are depicted as the serial ribbon and pin connection, however it is contemplated that this connection could be any other suitable connection.

Fabrication tools are products of intensive cost cutting pressures. This can result in circuits and chips using fewer connections and relying on serial connections. The serial connections between the control board 108 and the handling machine 102, or between the control board 108 and its many external sensors and attachments, can be any serial communication connection including the recommended standard 232 or its related standards, the serial peripheral interface, the inter-integrated circuit bus, the peripheral component interconnect express, or the like.

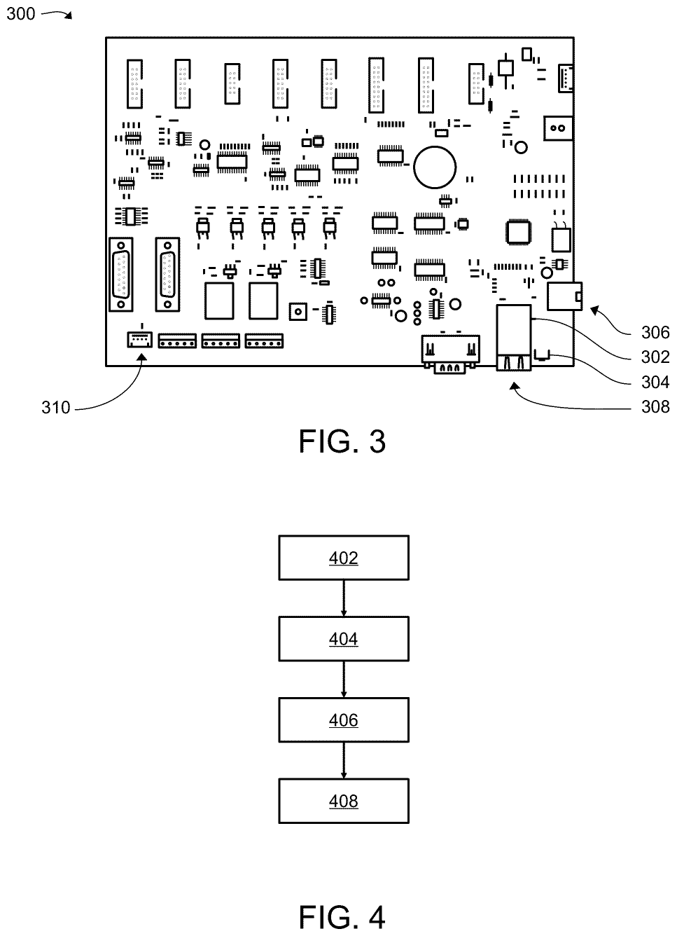

Referring now to FIG. 3, therein is shown a top view of a control board 300 in a second embodiment. The control board 300 of the second embodiment resembles the control board 108 of the first embodiment and can be described similarly, with the exceptions set forth below.

The primary difference between the control board 300 of the second embodiment and the control board 108 of FIG. 2 in the first embodiment, is that the control board 300 can collect the process information 110 of FIG. 1 through the serial connection 114 without the need to pull the process information 110 from the temperature monitoring connection 204, ground monitoring connection 208, sensor interface connection 212, tester interface connection 214, keypad connection 216, sort shuttle connection 220, or run-stop connection 222, all of FIG. 2. The process information 110 can be captured by sending a command from the serial connection 114 of the control board 300 to the handling machine 102 requesting the process information 110.

The control board 300 is depicted having a transient-voltage-suppression diode 302 and a resettable fuse 304 on a power supply line 306 to improve power stability and resolve issues of fuses blowing when a surge current enters the circuit.

The control board 300 is further shown with the network connections 168 converted to a transmission control protocol and internet protocol (TCP/IP) connection 308. The control board 300 can provide a separate vibration monitoring connection 310.

The vibration monitoring connection 310 can provide a connection between the vibration sensors 140 of FIG. 1. The vibration monitoring connection 310 can for example be a serial connection such as the I2C connection.

Referring now to FIG. 4, therein is shown a method of operating the control system 100. The method of operating the fabrication control system can comprise: detecting a status with a control board communicatively coupled to a semiconductor fabrication tool in a block 402; collecting process information from the semiconductor fabrication tool with the control board based on the status changing or a predetermined time elapsing in a block 404; storing the process information to a server with the control board communicatively coupled to the server by a network connection in a block 406; and engaging an auto-stop mechanism of the semiconductor fabrication tool to prevent the semiconductor fabrication tool from running based on the process information being wrong in a block 408.

Thus, it has been discovered that the control system furnishes important and heretofore unknown and unavailable solutions, capabilities, and functional aspects. The resulting configurations are straightforward, cost-effective, uncomplicated, highly versatile, accurate, sensitive, and effective, and can be implemented by adapting known components for ready, efficient, and economical manufacturing, application, and utilization.

The control system includes the integration of ground monitoring sensors, temperature sensors, light pole sensors, jam sensors, and bin sensors to provide a closed-loop control system with the handler auto-stop while providing automatic collection of important process information that saves man hours and improves tool availability while simultaneously providing increased control over important production controls leading to improved quality control. The control system therefore can provide continuous ground monitoring, auto-stop capability, and real time yield monitoring with auto-stop when a trigger is reached.

While the control system has been described in conjunction with a specific best mode, it is to be understood that many alternatives, modifications, and variations will be apparent to those skilled in the art in light of the preceding description. Accordingly, it is intended to embrace all such alternatives, modifications, and variations, which fall within the scope of the included claims. All matters set forth herein or shown in the accompanying drawings are to be interpreted in an illustrative and non-limiting sense.

What is claimed is:

1. A method of operating a fabrication control system comprising:
detecting a status of a semiconductor fabrication tool with a control board communicatively coupled thereto;
collecting process information from the semiconductor fabrication tool with the control board based on the status changing or a predetermined time elapsing; and
engaging an auto-stop mechanism of the semiconductor fabrication tool with the control board to prevent the semiconductor fabrication tool from running based on the process information being wrong.

2. The method of claim 1 wherein collecting the process information includes collecting: a product count, a temperature reading, a ground reading, a vibration reading, a jam reading, soak time data, sitemap data, debagging data, or fault data.

3. The method of claim 1 wherein collecting the process information includes collecting the process information with a serial connection between the control board and the semiconductor fabrication tool.

4. The method of claim 1 wherein engaging the auto-stop mechanism includes engaging the auto-stop mechanism wired into a door interlock of the semiconductor fabrication tool.

5. The method of claim 1 wherein engaging the auto-stop mechanism includes engaging the auto-stop mechanism based on the process information exceeding a threshold.

6. A method of operating a fabrication control system comprising:
detecting a status with a control board communicatively coupled to a semiconductor fabrication tool;
collecting process information from the semiconductor fabrication tool with the control board based on the status changing or a predetermined time elapsing;
storing the process information to a server with the control board communicatively coupled to the server by a network connection; and
engaging an auto-stop mechanism of the semiconductor fabrication tool to prevent the semiconductor fabrication tool from running based on the process information being wrong.

7. The method of claim 6 further comprising sending a response from the server to the control board, the response indicating a connection status between the control board and the server.

8. The method of claim 6 further comprising collecting an index time, a number of products that passed, a number of products that failed, a total number of products, or a lot number from a testing machine communicatively coupled to the server.

9. The method of claim 6 wherein engaging the auto-stop mechanism includes engaging the auto-stop mechanism based on a web service running on the server determining the process information is wrong.

10. The method of claim 6 further comprising determining a product count through the semiconductor fabrication tool, a product count through the semiconductor fabrication tool over time, or a product count through the semiconductor fabrication tool per jam with a web service running on the server.

11. A fabrication control system comprising a control board configured to:
detect a status of a semiconductor fabrication tool with the control board communicatively coupled thereto;
collect process information from the semiconductor fabrication tool based on the status changing or a predetermined time elapsing; and
engage an auto-stop mechanism of the semiconductor fabrication tool to prevent the semiconductor fabrication tool from running based on the process information being wrong.

12. The system of claim 11 wherein the control board is configured to collect a product count, a temperature reading, a ground reading, a vibration reading, a jam reading, soak time data, sitemap data, debagging data, or fault data.

13. The system of claim 11 wherein the control board is configured to collect the process information with a serial connection between the control board and the semiconductor fabrication tool.

14. The system of claim 11 wherein the control board is configured to engage the auto-stop mechanism wired into a door interlock of the semiconductor fabrication tool.

15. The system of claim 11 wherein the control board is configured to engage the auto-stop mechanism based on the process information exceeding a threshold.

16. The system of claim 11 wherein the control board is configured to store the process information to a server with a network connection therebetween.

17. The system of claim 16 wherein the control board is configured to receive a response from the server, the response indicating a connection status between the control board and the server.

18. The system of claim 16 wherein the control board is configured to collect data types including: a handler bin reading, a handler jam reading, a sitemap data, a temperature reading, or a soak time from a serial connection based on the control board sending a query for each of the data types.

19. The system of claim 16 wherein the control board is configured to engage the auto-stop mechanism based on a web service running on the server determining the process information is wrong.

20. The system of claim 16 further comprising determining a product count through the semiconductor fabrication tool, a product count through the semiconductor fabrication tool over time, or a product count through the semiconductor fabrication tool per jam with a web service running on the server and based on the process information collected by the control board.
